(19) United States
(12) Patent Application Publication
(10) Pub. No.: US 2026/0182006 A1
(43) Pub. Date: Jun. 25, 2026

(54) Gallium oxide junction field effect transistor

(71) Applicant: POWER CUBESEMI INC., Seongnam-si (KR)

(72) Inventors: Sola WOO, Gwacheon-si (KR); Taeeun LEE, Busan (KR); Sin Su KYOUNG, Hanam-si (KR); Tai Young KANG, Gwangju-si (KR)

(73) Assignee: POWER CUBESEMI INC., Seongnam-si (KR)

(21) Appl. No.: 19/425,240

(22) Filed: Dec. 18, 2025

(30) Foreign Application Priority Data
Dec. 24, 2024 (KR) 10-2024-0195052
Oct. 16, 2025 (KR) 10-2025-0149509

(51) Int. Cl. H10D 84/00; H10D 8/00; H10D 8/01; H10D 30/01; H10D 30/80; H10D 62/10; H10D 62/60; H10D 62/82; H10D 64/23; H10D 64/27; H10D 84/01

(52) U.S. Cl. CPC H10D 84/101; H10D 8/053; H10D 8/825; H10D 30/0516; H10D 30/801; H10D 62/103; H10D 62/124; H10D 62/60; H10D 62/8271; H10D 64/256; H10D 64/411; H10D 84/0107

(57) ABSTRACT

Gallium oxide junction field effect transistor disclosed. Gallium oxide junction field effect transistor includes a gallium oxide substrate, an n-type gallium oxide epitaxial layer epitaxially grown on the gallium oxide substrate, a source electrode and a drain electrode formed on the n-type gallium oxide epitaxial layer, and a npn gate including a p-type nickel oxide layer located on the n-type gallium oxide epitaxial layer between the source electrode and the drain electrode, a p-type nickel diffusion region extending into the n-type gallium oxide epitaxial layer from a junction between the p-type nickel oxide layer and the n-type gallium oxide epitaxial layer, and an n-type gallium oxide thin film formed on the p-type nickel oxide layer.

### CROSS-REFERENCE TO RELATED APPLICATION

The present application claims priority under 35 U.S.C. § 119(a) to Korean Patent Application number 10-2024-0195052, filed on Dec. 24, 2024, and Korean Patent Application number 10-2025-0149509, filed on Oct. 16, 2025 in the Korean Intellectual Property Office, which are incorporated herein by reference in their entireties.

### BACKGROUND

The present invention relates to a lateral gallium oxide transistor.

Due to the rapid developments of the power, automotive electronics and home appliance industries, the demand for high-performance power semiconductor devices has exploded. Due to ongoing research, ultra-wideband semiconductors including silicon carbide and gallium nitride have achieved higher performance than silicon-based power semiconductors. However, they have the disadvantages of difficult bulk single crystal growth and high production costs.

Gallium oxide is an emerging ultra-wideband semiconductor material after silicon carbide and gallium nitride, with a bandgap of about 4.7 to about 4.9 eV, far beyond the bandgap width of silicon carbide and gallium nitride, and a theoretical breakdown field of 8 MV/cm. Gallium oxide is particularly capable of growing substrates and epitaxial layers at relatively low cost compared to other ultra-wideband semiconductor materials. However, because the effective hole mass of an appropriate p-type dopant is large and the acceptor activation energy is high, it is difficult to implement a pn homojunction-based β-Ga₂O₃ device.

### SUMMARY

According to one aspect of the present invention, there is provided a gallium oxide junction field effect transistor, including a gallium oxide substrate, an n-type gallium oxide epitaxial layer epitaxially grown on the gallium oxide substrate, a source electrode and a drain electrode formed on the n-type gallium oxide epitaxial layer, and a npn gate including a p-type nickel oxide layer located on the n-type gallium oxide epitaxial layer between the source electrode and the drain electrode, a p-type nickel diffusion region extending into the n-type gallium oxide epitaxial layer from a junction between the p-type nickel oxide layer and the n-type gallium oxide epitaxial layer, and an n-type gallium oxide thin film formed on the p-type nickel oxide layer.

In one embodiment, the p-type nickel diffusion region may be formed by nickel diffusing into the n-type gallium oxide epitaxial layer from the p-type nickel oxide layer.

In one embodiment, a thickness difference between the p-type nickel diffusion region and the n-type gallium oxide epitaxial layer may be in a range from 0.07 μm to 0.1 μm.

In one embodiment, the n-type gallium oxide thin film and the p-type nickel oxide layer may form a first pn heterojunction diode, the p-type nickel oxide layer and the n-type gallium oxide epitaxial layer may form a second pn heterojunction diode, and the npn gate may constitute a back-to-back diode in which the first pn heterojunction diode and the second pn heterojunction diode are connected in opposite directions.

In one embodiment, a hole concentration of the p-type nickel oxide layer may be greater than a doping concentration of the gallium oxide epitaxial layer.

In one embodiment, the hole concentration of the p-type nickel oxide layer may be ten times greater than the doping concentration of the gallium oxide epitaxial layer.

In one embodiment, a thickness of the n-type gallium oxide thin film may be in a range from 0.03 μm to 0.05 μm.

In one embodiment, a doping concentration of the n-type gallium oxide thin film may be 1E19 cm⁻³.

According to another aspect of the present invention, there is provided a method for manufacturing a gallium oxide junction field effect transistor with an npn gate, including preparing an n-type gallium oxide substrate on which an n-type gallium oxide epitaxial layer is epitaxially grown, forming a p-type nickel oxide layer on the n-type gallium oxide epitaxial layer, forming an n-type gallium oxide thin film on the p-type nickel oxide layer, removing the p-type nickel oxide layer and the n-type gallium oxide thin film formed outside a gate region in where the npn gate is formed and forming a p-type nickel diffusion region in the n-type gallium oxide epitaxial layer by diffusion from the p-type nickel oxide layer.

In one embodiment, the method may further include, before the forming a p-type nickel oxide layer on the n-type gallium oxide epitaxial layer, forming an insulating layer on the n-type gallium oxide epitaxial layer in which a source region, a drain region, and the gate region are formed between the source region and the drain region.

In one embodiment, the method may further include, after the step of forming the insulating layer on the n-type gallium oxide epitaxial layer where the source region, the drain region, and the gate region are formed between the source region and the drain region, forming a source and a drain in the source region and the drain region, respectively.

In one embodiment, the n-type gallium oxide thin film may be formed with a thickness in a range from 0.03 μm to 0.05 μm.

In one embodiment, the n-type gallium oxide thin film may formed with a doping concentration of 1E19 cm⁻³.

In one embodiment, a hole concentration of the p-type nickel oxide layer may be ten times greater than a doping concentration of the gallium oxide epitaxial layer.

In one embodiment, a thickness difference between the p-type nickel diffusion region and the n-type gallium oxide epitaxial layer may be in a range from 0.07 μm to 0.1 μm.

### BRIEF DESCRIPTION OF DRAWINGS

Hereinafter, embodiments of the invention will be described with reference to the accompanying drawings. For the purpose of easy understanding of the invention, the same elements will be referred to by the same reference signs. Configurations illustrated in the drawings are examples for describing the invention, and do not restrict the scope of the invention. Particularly, in the drawings, some elements are slightly exaggerated for the purpose of easy understanding of the invention. Since the drawings are used to easily understand the invention, it should be noted that widths, depths, and the like of elements illustrated in the drawings might change at the time of actual implementation thereof. Meanwhile, throughout the detailed description of the invention, the same components are described with reference to the same reference numerals.

FIG. 1 schematically illustrates a gallium oxide junction field effect transistor;

FIG. 2A, FIG. 2B, FIG. 2C, FIG. 2D, FIG. 2E, FIG. 2F, FIGS. 2G and 2H schematically illustrate a process for fabricating a gallium oxide junction field effect transistor;

FIG. 3A and FIG. 3B schematically illustrate the normally-off operation of the gallium oxide junction field effect transistor according to a gate voltage;

FIG. 4 is a graph showing the gate voltage operating range of the gallium oxide junction field effect transistor;

FIG. 5 is a graph showing the operating range of the gate voltage of the gallium oxide junction field effect transistor according to the thickness and doping concentration of the n-type gallium oxide thin film;

FIG. 6 is a graph showing the threshold voltage of the gallium oxide junction field effect transistor according to the doping concentration of the n-type gallium oxide thin film;

FIG. 7 and FIG. 8 are graphs showing the threshold voltage of the gallium oxide junction field effect transistor according to the thickness of the n-type gallium oxide thin film;

FIG. 9 is a graph showing the threshold voltage of the gallium oxide junction field effect transistor according to the nickel diffusion depth and the channel layer thickness;

FIG. 10 is a graph showing the threshold voltage of the gallium oxide junction field effect transistor according to the hole concentration of the p-type nickel oxide layer; and

FIG. 11 is a graph showing the drain voltage-current and on-resistance of the gallium oxide junction field effect transistor according to the gate voltage.

### DETAILED DESCRIPTION

Embodiments which will be described below with reference to the accompanying drawings can be implemented singly or in combination with other embodiments. But this is not intended to limit the present invention to a certain embodiment, and it should be understood that all changes, modifications, equivalents or replacements within the spirits and scope of the present invention are included. Especially, any of functions, features, and/or embodiments can be implemented independently or jointly with other embodiments. Accordingly, it should be noted that the scope of the invention is not limited to the embodiments illustrated in the accompanying drawings.

Terms such as first, second, etc., may be used to refer to various elements, but these elements should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings.

Hereinafter, embodiments of the present invention will be described in detail with reference to the accompanying drawings.

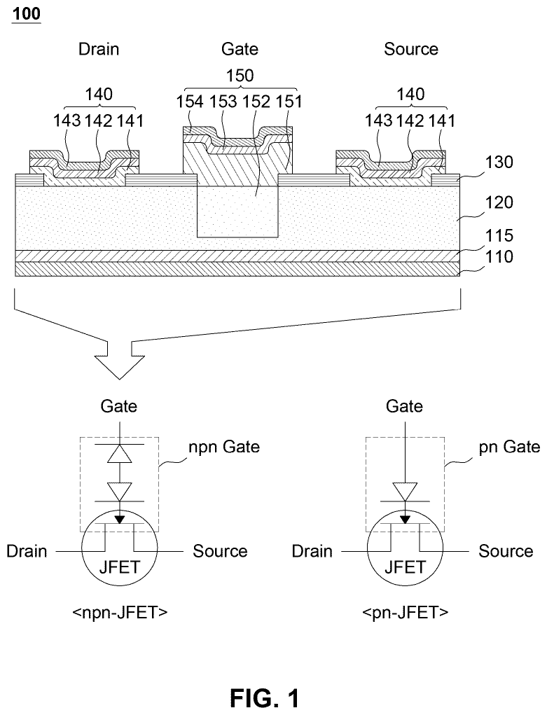

FIG. 1 schematically illustrates a gallium oxide junction field effect transistor.

Referring to FIG. 1, the gallium oxide junction field effect transistor (hereinafter, npn-JFET) 100 may include a gallium oxide substrate 110, a gallium oxide buffer layer 115, an n-type gallium oxide epitaxial layer 120, an insulating layer 130, source/drain electrode 141, 142, 143 (collectively referred to as 140), and a npn gate 151, 152, 153, 154 (collectively referred to as 150).

The gallium oxide substrate 110 may be fabricated with single crystal β-gallium oxide (β-Ga₂O₃) doped with an n-type dopant, for example, Fe, and an UID (Unintentionally doped) gallium oxide buffer layer 115 may be formed on the gallium oxide substrate 110.

The n-type gallium oxide epitaxial layer 120 is β-gallium oxide doped with an n-type dopant grown on the gallium oxide buffer layer 115. The n-type dopant may be, for example, silicon (Si), and the doping concentration of the n-type dopant may be about 1E17 cm⁻³, which may be at least 100 times or more than the doping concentration of the gallium oxide buffer layer 115. The thickness of the n-type gallium oxide epitaxial layer 120 may be about 0.5 μm.

The insulating layer 130 may be formed by depositing silicon oxide (SiO₂) on the n-type gallium oxide epitaxial layer 120 and can define a source/drain region and a gate region corresponding to the source electrode/drain electrode 140 and the npn gate 150. The gate region may be located between the source region and the drain region. The source/drain region and the gate region are regions where the insulating layer 130 is etched to expose the n-type gallium oxide epitaxial layer 120 at positions where the source/drain 140 and the npn gate 150 are to be formed. The insulating layer 130 deposited on the n-type gallium oxide epitaxial layer 120 may serve as a field plate.

The source and drain electrodes 140 may have the same stacked structure and be formed in the source/drain region. For example, the n-type contact layer 141 that contacts the n-type gallium oxide epitaxial layer 120 can be fabricated by depositing indium tin oxide (ITO). A first electrode layer 142 may be formed by depositing titanium (Ti) on the n-type contact layer 141, and a second electrode layer 143 may be formed by depositing gold (Au) on the first electrode layer 142.

The npn gate 150 may include a p-type nickel oxide (NiO) layer 151, an n-type gallium oxide thin film 153, a gate electrode layer 154 sequentially stacked in the gate region, and a p-type nickel diffusion region 152 formed by nickel (Ni) diffusing into the n-type gallium oxide epitaxial layer 120. The p-type nickel oxide layer 151 may be formed by depositing nickel oxide on the n-type gallium oxide epitaxial layer 120, the n-type gallium oxide thin film 153 may be formed by depositing gallium oxide on the p-type nickel oxide layer 151, and the gate electrode layer 154 may be formed by depositing nickel on the n-type gallium oxide thin film 153.

The thickness of the p-type nickel oxide layer 151 is about 0.1 μm or more, preferably about 0.25 μm, and the hole concentration is about $1E19 cm⁻³, which may be at least 10 times or more than the doping concentration of the n-type gallium oxide epitaxial layer 120.

The p-type nickel diffusion region 152 may be formed toward the inside of the n-type gallium oxide epitaxial layer 120 at the junction of the p-type nickel oxide layer 151 and the n-type gallium oxide epitaxial layer 120. When the hole concentration of the p-type nickel oxide layer 151 is about 10 times larger than the doping concentration of the n-type gallium oxide epitaxial layer 120, the p-type nickel diffusion region 152 may be formed to a thickness of about 0.4 μm, and the thickness difference between the n-type gallium oxide epitaxial layer 120 and the p-type nickel diffusion region 152 may be about 0.1 μm. That is, the thickness of the n-type gallium oxide epitaxial layer 120 located between the bottom of the p-type nickel diffusion region 152 and the top of the gallium oxide buffer layer 115 may increase to about 0.1 μm or more when the doping concentration of the n-type gallium oxide epitaxial layer 120 decreases, which may not be suitable for implementing a Normally-off gallium oxide JFET.

To increase the maximum driving current, a Normally-off gallium oxide JFET can be implemented by increasing at least one of the doping concentration of the n-type gallium oxide epitaxial layer 120, the hole concentration of the p-type nickel oxide layer 151, the thickness of the n-type gallium oxide epitaxial layer 120, and the thickness of the p-type nickel diffusion region 152. For example, if the hole concentration of the p-type nickel oxide layer 151 is increased to about 1E20 cm⁻³ and the doping concentration of the n-type gallium oxide epitaxial layer 120 is increased to about 1E18 cm⁻³, the thickness of the n-type gallium oxide epitaxial layer 120 located between the p-type nickel diffusion region 152 and the gallium oxide buffer layer 115 may be about 0.07 μm or less, hereby facilitating implementation of a normally-off operation.

The thickness of the n-type gallium oxide thin film 153 may be about 0.01 μm to about 0.09 μm, preferably about 0.03 μm to about 0.05 μm, and most preferably about 0.03 μm, and the doping concentration may be about 1E18 cm⁻³ to about 1E19 cm⁻³, preferably about 1E19 cm⁻³.

The n-type gallium oxide thin film 153 and the p-type nickel oxide layer 151 may form a first pn heterojunction diode, and the p-type nickel diffusion region 152 and the n-type gallium oxide epitaxial layer 120 may form a second pn heterojunction diode. The npn-JFET 100, as shown, can be represented by an npn-JFET equivalent circuit. The npn gate 150 includes a back-to-back diode formed by two pn heterojunction diodes connected in opposite directions.

The JFET with a pn gate (hereinafter, pn-JFET) shown as a comparative example in FIG. 1 is configured only of a pn heterojunction formed between a p-type nickel oxide layer and an n-type gallium oxide epitaxial layer, by depositing the p-type nickel oxide layer on the n-type gallium oxide epitaxial layer. To make the pn-JFET Normally-off, the lower part of the pn gate must be etched to implement a recessed gate. However, the etching process not only increases cost and time, but also causes damage to the channel, which may reduce the reliability of the JFET.

In addition, if a gate voltage greater than or equal to the turn-on voltage of the pn heterojunction diode is applied to the pn-JFET, the pn heterojunction turns on, thereby limiting the operating range of the gate voltage, which made it difficult to apply to power electronic systems. In contrast, the npn gate 150 is clamped by the back-to-back diode even when a high voltage of +30 V or more is applied, which can significantly increase the operating range of the gate voltage. Compared to the conventional pn gate, the depletion layer formed toward the n-type gallium oxide epitaxial layer 120 at the pn heterojunction of the p-type nickel diffusion region 152 and the n-type gallium oxide epitaxial layer 120 can be further expanded. In addition, when a positive voltage is applied to the npn gate 150, a reverse voltage is applied to the first pn heterojunction diode, limiting the leakage current to the n-type gallium oxide epitaxial layer 120, and even when a positive voltage is applied to the drain electrode 140, a reverse voltage is applied to the second pn heterojunction diode, which can limit the leakage current between the npn gate 150 and the drain electrode 140, thereby effectively insulating the npn gate 150.

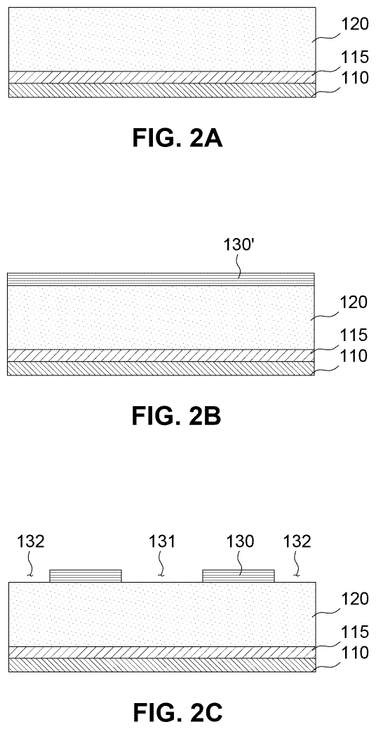

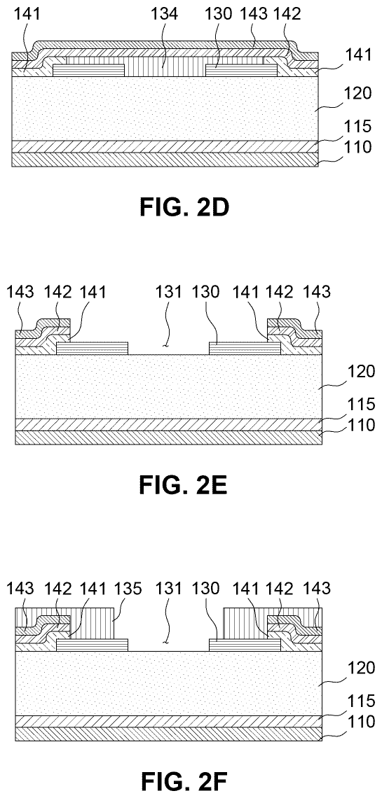

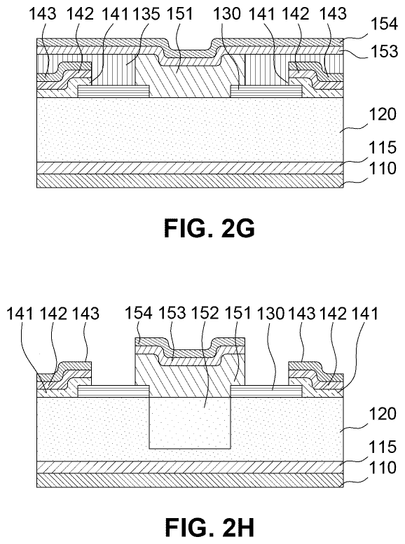

FIGS. 2A to 2H schematically illustrate a process for fabricating a gallium oxide junction field effect transistor.

In FIG. 2A, the n-type gallium oxide epitaxial layer 120 is epitaxially formed on the gallium oxide buffer layer 115. Before forming the n-type gallium oxide epitaxial layer 120, foreign matter on the n-type gallium oxide substrate 110 on which the gallium oxide buffer layer 115 is formed may be removed by cleaning and plasma treatment. The n-type gallium oxide epitaxial layer 120 may be formed by epitaxially growing β-gallium oxide doped with, for example, silicon (Si) with a doping concentration of about 1E17 cm⁻³ to a thickness of about 0.5 μm. The n-type gallium oxide epitaxial layer 120 may be formed by, for example, HVPE (Halide vapor phase epitaxy), MOCVD (Metalorganic chemical vapor deposition), Mist CVD, MBE (Molecular Beam Epitaxy), PLD (Pulsed laser deposition), or AD (Aerosol deposition).

In FIG. 2B, a silicon oxide layer 130′ is deposited on the upper surface of the n-type gallium oxide epitaxial layer 120. The silicon oxide layer 130′ can be formed by depositing silicon oxide by chemical vapor deposition or spin coating.

In FIG. 2C, the insulating layer 130 for defining the gate region 131 and the source/drain region 132 may be formed by etching the silicon oxide layer 130′. For example, a photoresist layer is stacked on the silicon oxide layer 130′. The photoresist layer can be formed by spin coating a photoresist on the silicon oxide layer 130′ and then soft baking it. Next, a photoresist mask is formed by removing the photoresist in the regions of the photoresist layer where the gate region 131 and the source/drain region 132 will be formed. Next, the insulating layer 130 is formed by etching the silicon oxide layer 130′ exposed by the photoresist mask. Next, the photoresist mask is removed.

In FIG. 2D, the source electrode/drain electrode 140 may be formed in the source/drain region 132. For example, a photoresist layer is stacked on the upper surface of the n-type gallium oxide epitaxial layer 120 on which the insulating layer 130 is formed. Next, the photoresist layer formed in the source/drain region 132 is removed to form a photoresist mask 134 that exposes the source/drain region 132 and covers the gate region 131. Next, the n-type contact layer 141, the first electrode layer 142, and the second electrode layer 143 may be sequentially deposited, for example, by sputtering.

In FIG. 2E, the n-type contact layer 141, the first electrode layer 142, and the second electrode layer 143 deposited on regions other than the source/drain region 132 may be removed119. Next, the photoresist mask 134 may be removed.

In FIG. 2F, a photoresist layer may be stacked on the upper surface of the n-type gallium oxide epitaxial layer 120 and on the source electrode/drain electrode 140. Through photo and etching processes, the photoresist layer formed in the gate region 131 may be removed to form a photoresist mask 135 where the gate region 131 is exposed.

In FIG. 2G, to form the npn gate 150, the p-type nickel oxide layer 151, the n-type gallium oxide thin film 153, and the gate electrode layer 154 may be sequentially formed on the gate region 131.

The p-type nickel oxide layer 151 may be deposited to a thickness of about 0.25 μm on the upper surface of the n-type gallium oxide epitaxial layer 120 exposed in the gate region 131 using a nickel oxide target or a nickel target.

The n-type gallium oxide thin film 153 may be deposited by sputtering a gallium oxide target, or by HVPE, MOCVD, Mist CVD, MBE, PLD, or AD.

The gate electrode layer 154 may be deposited on the n-type gallium oxide thin film 153 by sputtering a nickel target.

In FIG. 2H, the p-type nickel oxide layer 151, the n-type gallium oxide thin film 153, and the gate electrode layer 154 in regions other than the gate region 131 may be removed. Thereafter, a post-annealing process is performed to form the p-type nickel diffusion region 152. During the post-annealing, nickel ions of the p-type nickel oxide layer 151 diffuse into the n-type gallium oxide epitaxial layer 120 to form the p-type nickel diffusion region 152. The p-type nickel diffusion region 152 and the n-type gallium oxide epitaxial layer 120 form a pn heterojunction. The post-annealing may be performed, for example, at about 300° C. for about 30 seconds in an Ar atmosphere. The post-annealing conditions may vary depending on various parameters such as the concentration and the thickness of the p-type nickel diffusion region 152.

The p-type region can be formed within the n-type gallium oxide epitaxial layer 120 through the diffusion of nickel without an etching process. Forming a p-type region within the gallium oxide epitaxial layer by etching not only increases time and cost, but also causes interface damage, which can reduce the performance of the JFET. Forming the p-type region within the gallium oxide epitaxial layer by diffusion can solve the problems of the etching process.

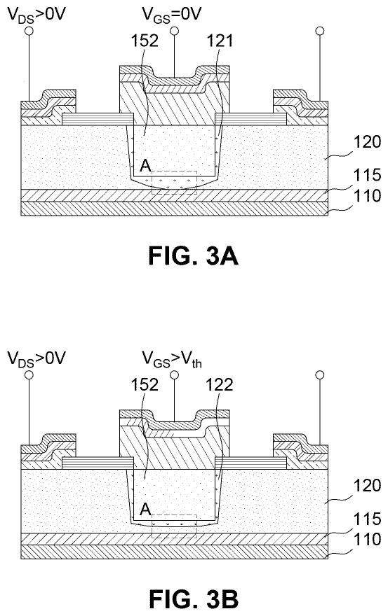

FIGS. 3A and 3B schematically illustrate the normally-off operation of the gallium oxide junction field effect transistor according to a gate voltage.

Referring to FIG. 3A, a region A is the n-type gallium oxide epitaxial layer 120 located between the p-type nickel diffusion region 152 and the gallium oxide buffer layer 115, which corresponds to the channel through which current flows. Even when no voltage is applied to the npn gate 150 (V_{G}=0), the depletion region 121 due to the pn heterojunction between the p-type nickel diffusion region 152 and the n-type gallium oxide epitaxial layer 120 extends from at least a part of the region A to the gallium oxide buffer layer 115, so no current flows even if a positive voltage (V_{DS}>0V) is applied between the drain electrode and the source electrode.

Meanwhile, referring to FIG. 3B, when a gate voltage V_{G} greater than or equal to the threshold voltage Vt is applied to the npn gate 150, the depletion region 121 due to the pn heterojunction between the p-type nickel diffusion region 152 and the n-type gallium oxide epitaxial layer 120 shrinks from the region A to the p-type nickel diffusion region 152, forming a channel. Therefore, a current due to the positive voltage (V_{DS}>0V) applied between the drain electrode and the source electrode flows through the channel.

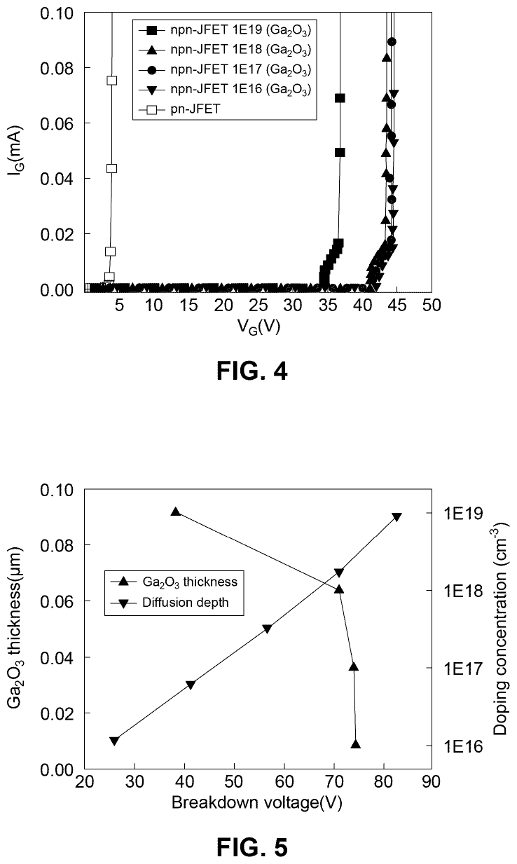

FIG. 4 is a graph showing the gate voltage operating range of the gallium oxide junction field effect transistor.

Referring to FIG. 4, the npn-JFET 100 according to one embodiment of the present disclosure is equipped with the npn gate 150 (indicated as npn-JFET), and the conventional JFET is equipped with a pn gate (indicated as pn-JFET). The npn-JFET 100 was fabricated to have an n-type gallium oxide thin film 153 with doping concentrations of about 1E16 cm⁻³, 1E17 cm⁻³, 1E18 cm⁻³ and 1E19 cm⁻³. The remaining parameters were fabricated to be substantially the same except for the doping concentration of the n-type gallium oxide thin film 153. In the case of the pn-JFET, it is confirmed that a large leakage current is generated as the pn heterojunction between the p-type nickel oxide and the n-type gallium oxide epitaxial layer turns on at a gate voltage of about 3.4 V. In contrast, in the npn-JFET 100, the minimum operating range of the gate voltage is about 30 V or more across the entire doping concentration range of the n-type gallium oxide thin film 153. Furthermore, unlike the pn-JFET, the leakage current does not increase sharply at the threshold voltage. In summary, it can be confirmed that the threshold voltage increases as the doping concentration of the n-type gallium oxide thin film 153 decreases.

FIG. 5 is a graph showing the operating range of the gate voltage of the gallium oxide junction field effect transistor according to the thickness and doping concentration of the n-type gallium oxide thin film.

Referring to FIG. 5, when the doping concentration of the n-type gallium oxide thin film 153 is fixed at about 1E18 cm⁻³ and only the thickness of the n-type gallium oxide thin film 153 is increased by about 0.02 μm from about 0.01 μm, the maximum operating range of the gate voltage of the npn-JFET 100 increases in proportion to the thickness of the n-type gallium oxide thin film150. That is, this means that the breakdown voltage of the npn gate 150 also decreases when the thickness of the n-type gallium oxide thin film decreases.

On the other hand, when the thickness is fixed at about 0.07 μm and the doping concentration of the n-type gallium oxide thin film 153 is changed to about 1E16 cm⁻³, 1E17 cm⁻³, 1E18 cm⁻³ and 1E19 cm⁻³, the maximum operating range of the gate voltage of the npn-JFET 100 decreases in inverse proportion to the increase in doping concentration. That is, this means that the electric field of the p-type nickel oxide layer/n-type gallium oxide thin film junction decreases when the doping concentration of the n-type gallium oxide thin film 153 decreases, so the breakdown voltage of the npn gate 150 increases.

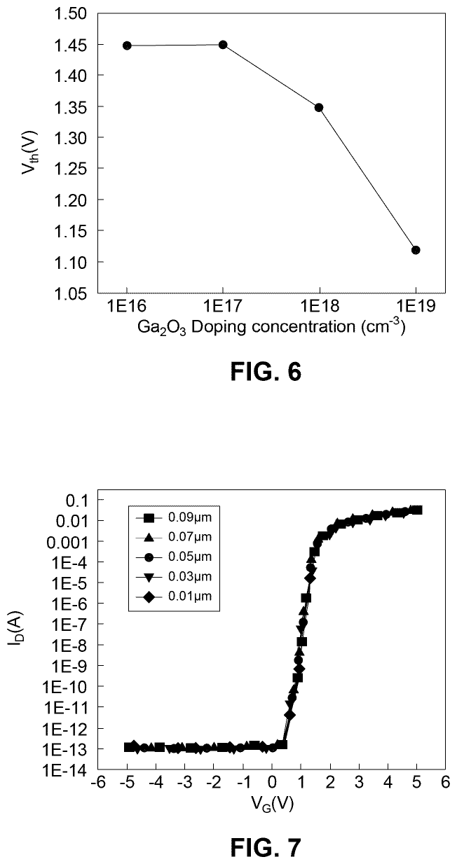

FIG. 6 is a graph showing the threshold voltage of the gallium oxide junction field effect transistor according to the doping concentration of the n-type gallium oxide thin film.

Referring to FIG. 6, when the doping concentration of the n-type gallium oxide thin film 153 increases to about 1E16 cm⁻³, 1E17 cm⁻³, 1E18 cm⁻³ and 1E19 cm⁻³, the threshold voltage of the npn-JFET 100 decreases from about 1.45 V to about 1.13 V. That is, the doping concentration of the n-type gallium oxide thin film 153 and the threshold voltage of the npn-JFET 100 are inversely proportional.

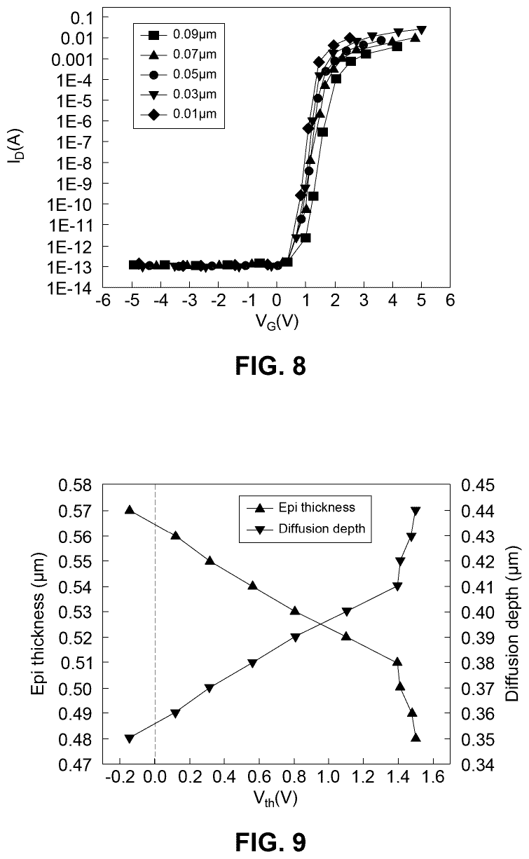

FIGS. 7 and 8 are graphs showing the threshold voltage of the gallium oxide junction field effect transistor according to the thickness of the n-type gallium oxide thin film.

Referring to FIGS. 7 and 8 together, the drain current Ip was measured by applying a gate voltage V_{G} of −5 V to +5 V to the npn-JFET 100 in which the doping concentration of the n-type gallium oxide thin film 153 was fixed at about 1E19 cm⁻³ (FIG. 7) and about 1E16 cm⁻³ (FIG. 8), and the thickness of the n-type gallium oxide thin film 153 was increased by 0.02 μm from about 0.01 μm. When the doping concentration of the n-type gallium oxide thin film 153 is high (FIG. 7), the threshold voltage is constant regardless of the thickness of the thin film, whereas when the doping concentration is low (FIG. 8), the threshold voltage decreases as the thickness of the thin film decreases. This is because a voltage drop occurs due to the high resistance of the n-type gallium oxide thin film resulting from the low doping, lowering the voltage of the semiconductor thin film-nickel oxide layer junction.

FIG. 9 is a graph showing the threshold voltage of the gallium oxide junction field effect transistor according to the nickel diffusion depth and the channel layer thickness.

Referring to FIG. 9, it can be confirmed that the threshold voltage decreases as the thickness of the channel (region A in FIGS. 3A and 3B) increases and the diffusion depth of the p-type nickel diffusion region 152 decreases. In particular, if the thickness of the n-type gallium oxide epitaxial layer 120 is 0.565 μm or more and the diffusion depth of the p-type nickel diffusion region 152 is 0.355 μm or less (both in the region to the left of the dotted line), the threshold voltage becomes 0 V or less, and the JFET becomes Normally-on.

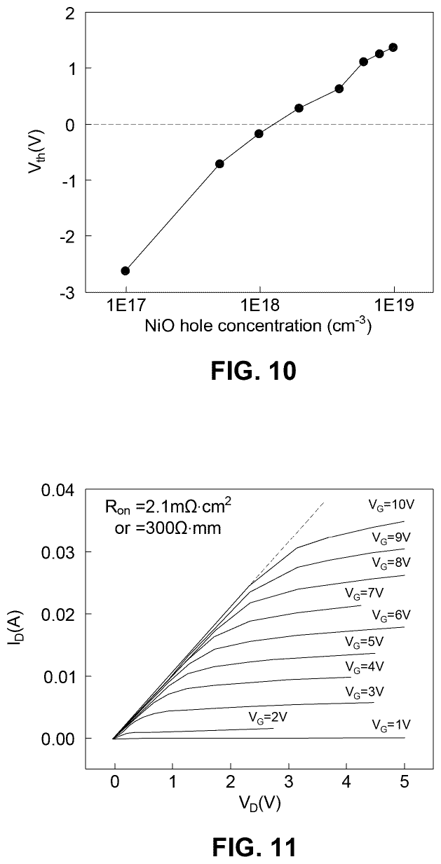

FIG. 10 is a graph showing the threshold voltage of the gallium oxide junction field effect transistor according to the hole concentration of the p-type nickel oxide layer.

Referring to FIG. 10, it can be confirmed that the threshold voltage decreases as the hole concentration of the p-type nickel oxide layer 151 decreases. In particular, if the hole concentration decreases to 1.5E18 cm⁻³ or less (the region below the dotted line), the threshold voltage becomes 0 V or less, and the JFET becomes Normally-on. That is, when the hole concentration of the p-type nickel oxide layer 151 decreases, the hole concentration of the p-type nickel diffusion region 152 also decreases, and the electron concentration of the n-type gallium oxide epitaxial layer 120 is less offset, so the hole concentration of the p-type nickel diffusion region 152 becomes lower than the electron concentration of the n-type gallium oxide epitaxial layer 120. As a result, when the drain voltage increases, the depletion region expands into the p-type nickel diffusion region 152 instead of the n-type gallium oxide epitaxial layer 120, and the threshold voltage decreases.

FIG. 11 is a graph showing the drain voltage-current and on-resistance of the gallium oxide junction field effect transistor according to the gate voltage.

The npn-JFET 100 was fabricated with an n-type gallium oxide epitaxial layer 120 of 0.5 μm thickness and 1E17 cm⁻³ doping concentration, a p-type nickel oxide layer 151 of 0.25 μm thickness and 1E19 cm⁻³ doping concentration, a p-type nickel diffusion region 152 of 0.4 μm thickness, and an n-type gallium oxide thin film 153 of 0.03 μm thickness and 1E19 cm⁻³ doping concentration. Referring to FIG. 11, from the result of measuring the drain voltage V_{D} and the drain current I_{D} of the npn-JFET 100 while adjusting the gate voltage V_{G} from about +1 V to about +10 V, it can be confirmed that the drain current I_{D} increases sharply as the gate voltage V_{G} increases. Despite the change in the gate voltage V_{G}, the on-resistance remains low at about 2.1 mΩ·cm².

The above description of the invention is exemplary, and those skilled in the art can understand that the invention can be modified in other forms without changing the technical concept or the essential feature of the invention. Therefore, it should be understood that the above-mentioned embodiments are exemplary in all respects, but are not definitive.

The scope of the invention is defined by the appended claims, not by the above detailed description, and it should be construed that all changes or modifications derived from the meanings and scope of the claims and equivalent concepts thereof are included in the scope of the invention.

What is claimed is:

1. A gallium oxide junction field effect transistor, comprising:
a gallium oxide substrate;
an n-type gallium oxide epitaxial layer epitaxially grown on the gallium oxide substrate;
a source electrode and a drain electrode formed on the n-type gallium oxide epitaxial layer; and
a npn gate comprising:
a p-type nickel oxide layer located on the n-type gallium oxide epitaxial layer between the source electrode and the drain electrode;
a p-type nickel diffusion region extending into the n-type gallium oxide epitaxial layer from a junction between the p-type nickel oxide layer and the n-type gallium oxide epitaxial layer; and
an n-type gallium oxide thin film formed on the p-type nickel oxide layer.

2. The gallium oxide junction field effect transistor of claim 1, wherein the p-type nickel diffusion region is formed by nickel diffusing into the n-type gallium oxide epitaxial layer from the p-type nickel oxide layer.

3. The gallium oxide junction field effect transistor of claim 2, wherein a thickness difference between the p-type nickel diffusion region and the n-type gallium oxide epitaxial layer is in a range from 0.07 μm to 0.1 μm.

4. The gallium oxide junction field effect transistor according to claim 1, wherein the n-type gallium oxide thin film and the p-type nickel oxide layer form a first pn heterojunction diode, the p-type nickel oxide layer and the n-type gallium oxide epitaxial layer form a second pn heterojunction diode, and the npn gate constitutes a back-to-back diode in which the first pn heterojunction diode and the second pn heterojunction diode are connected in opposite directions.

5. The gallium oxide junction field effect transistor of claim 1, wherein a hole concentration of the p-type nickel oxide layer is greater than a doping concentration of the n-type gallium oxide epitaxial layer.

6. The gallium oxide junction field effect transistor of claim 5, wherein the hole concentration of the p-type nickel oxide layer is ten times greater than the doping concentration of the n-type gallium oxide epitaxial layer.

7. The gallium oxide junction field effect transistor of claim 1, wherein a thickess of the n-type gallium oxide thin film is in a range from 0.03 μm to 0.05 μm.

8. The gallium oxide junction field effect transistor of claim 1, wherein a doping concentration of the n-type gallium oxide thin film is 1E19 cm⁻³.

9. A method for manufacturing a gallium oxide junction field effect transistor with an npn gate, comprising:
preparing an n-type gallium oxide substrate on which an n-type gallium oxide epitaxial layer is epitaxially grown;
forming a p-type nickel oxide layer on the n-type gallium oxide epitaxial layer;
forming an n-type gallium oxide thin film on the p-type nickel oxide layer;
removing the p-type nickel oxide layer and the n-type gallium oxide thin film formed outside a gate region in where the npn gate is formed; and
forming a p-type nickel diffusion region in the n-type gallium oxide epitaxial layer by diffusion from the p-type nickel oxide layer.

10. The method of claim 9, further comprising, before the forming of a p-type nickel oxide layer on the n-type gallium oxide epitaxial layer,
forming an insulating layer on the n-type gallium oxide epitaxial layer in which a source region, a drain region, and the gate region are formed,
wherein the gate region is formed between the source region and the drain region.

11. The method of claim 10, further comprising, after the forming of the insulating layer on the n-type gallium oxide epitaxial layer, forming a source and a drain in the source region and the drain region, respectively.

12. The method of claim 9, wherein the n-type gallium oxide thin film is formed with a thickness in a range from 0.03 μm to 0.05 μm.

13. The method of claim 9, wherein the n-type gallium oxide thin film is formed with a doping concentration of 1E19 cm⁻³.

14. The method of claim 9, wherein a hole concentration of the p-type nickel oxide layer is ten times greater than a doping concentration of the n-type gallium oxide epitaxial layer.

15. The method of claim 9, wherein a thickness difference between the p-type nickel diffusion region and the n-type gallium oxide epitaxial layer is in a range from 0.07 μm to 0.1 μm.
